(19) United States
(12) Patent Application Publication
(10) Pub. No.: US 2001/0052767 A1
(43) Pub. Date: Dec. 20, 2001

(54) Sorting control method of tested electric device

(76) Inventors: Yutaka Watanabe, Tokyo (JP); Haruki Nakajima, Tokyo (JP); Hiroki Ikeda, Tokyo (JP)

Correspondence Address: BIRCH STEWART KOLASCH & BIRCH, PO BOX 747, FALLS CHURCH, VA, 22040-0747, US

(21) Appl. No.: 09/879,127

(22) Filed: Jun. 13, 2001

(30) Foreign Application Priority Data
Jun. 13, 2000 (JP) 2000-177456

(51) Int. Cl. G01R 1/00

(52) U.S. Cl. 324/158.1

(57) ABSTRACT

A sorting control method of tested ICs for sorting and reloading tested ICs held on a test tray to customer trays in accordance with test results, wherein a calculating from the test results an occurrence rate of each category of tested ICs held on the test tray and starting reloading from ICs of a category having a low occurrence rate and when a second tray for holding ICs of the category is being changed, reloading of ICs of a category having a high occurrence rate is performed.

### BACKGROUND OF THE INVENTION

1. Field of the Invention

The present invention relates to an electric device testing apparatus for testing a semiconductor integrated circuit element and variety of other electric devices (hereinafter, also representatively referred to as an IC), in particular relates to a control method of sorting tested electric devices in accordance with test results.

2. Description of the Related Art

An electronic devices testing apparatus called a “handler” conveys a large number of ICs held on a tray to inside of a testing apparatus where the ICs are pressed against a test head, then the IC testing unit (tester) is made to perform a test. When the test is ended, the ICs are conveyed out from the test procedure and reloaded on trays in accordance with results of the tests so as to classify them into categories of good ICs and defective ones.

In a handler of the related art, there are some types wherein trays for holding the ICs to be tested or the tested ICs (hereinafter also referred to as “customer trays”) and trays conveyed circulating inside the handler (hereinafter referred to as “test trays”) are different, therefore, in such types of handlers, the ICs are switched between the customer trays and the test trays before and after the test, and in the testing processing wherein tests are carried out by contacting the ICs to the test head, ICs are pressed against the test head while being carried on the test trays.

When reloading the tested ICs on trays in accordance with the test results, empty customer trays for the number of categories, such as good ICs, defective ones, reexamination needed ones, are prepared, on which the ICs are reloaded. When a customer tray becomes full, it is conveyed out to be changed by a new empty tray.

There are some cases that the number of categories exceeds the number of general sorting of the handler due to examination specification of IC products. In this case, the handler of the related art deals with it by changing the customer trays.

However, since a reloading operation for sorting stops during changing the customer trays, so there is a disadvantage that the number of ICs to be processed per one hour reduces as the sorting number increases.

Also, when reloading ICs from a test tray to the customer trays, since the handler of the related art starts to reload from the next test tray only after all ICs held on one test tray are reloaded, the number of ICs to be processed per time reduces due to an increase of the sorting number. Furthermore, the reloading operation of ICs stops during changing test trays, thus the number of ICs to be processed per time further reduces.

### SUMMARY OF THE INVENTION

(1) An object of the present invention is to provide a control method of sorting tested electric devices which can maintain the number of devices to be processed per time even if the sorting number increases.

According to a first aspect of the present invention, there is provided a sorting control method of tested ICs for sorting and reloading tested ICs held on a first tray to second trays in accordance with test results, including the steps of calculating from the test results an occurrence rate of each category of tested ICs held on the first tray, and reloading ICs of a category having a high occurrence rate to two or more second trays.

Also according to a second aspect of the present invention, there is provided a sorting control method of tested ICs for sorting and reloading tested ICs held on a first tray to second trays in accordance with test results, including the steps of calculating from the test results an occurrence rate of each category of tested ICs held on the first tray, and starting reloading from ICs of a category having a low occurrence rate and when a second tray for holding ICs of the category is being changed, reloading of ICs of a category having a high occurrence rate is performed.

It is not particularly limited in the above invention, preferably, when first trays are placed respectively in at least two positions and ICs to be reloaded from one first tray to a corresponding second tray end up, reloading is performed from the other first tray to the second tray.

Also, it is not particularly limited in the above invention, preferably, even when the other first tray is being conveyed to a position of the one first tray, reloading of ICs from the other first tray is performed.

Also, it is not particularly limited in the above invention, preferably, when first trays are placed respectively in at least two positions and ICs are reloaded from one first tray to a second tray, while ICs are reloaded from the other first tray to the second tray.

Furthermore, it is not particularly limited in the above invention, preferably, a buffer section is provided between the first tray and the second tray, and when a second tray to which ICs held on the first tray are sorted is not placed, the ICs are temporally reloaded on the buffer section.

(2) In the first aspect of the present invention, an occurrence rate in each category is calculated from the test results as to tested electric devices held on a first tray, and electric devices in a category having high occurrence rate are reloaded on two or more second trays.

Electric devices in the category having a high occurrence rate becomes large in number to be reloaded, therefore, the number of times of changing the second trays also becomes large when reloading to the second trays. However, there are two or more second trays prepared for being reloaded in the present invention, so that while one second tray is being changed by becoming full, the other second tray can be reloaded ICs of that category and the reloading operation is not interrupted (needless to wait for a next second tray). As a result, the reloading operation can be performed continuously and the number of ICs to be processed per time can be increased.

According to the second aspect of the present invention, an occurrence rate in each category is calculated from the test results as to tested electric devices held on a first tray, and electric devices in a category having a low occurrence rate are reloaded first and those in a category having a high occurrence rate are reloaded while changing the second tray for the low occurrence category.

Namely, since the number of ICs to be reloaded is small for ICs in the low occurrence rate category, the larger the number of categories, the more frequency the second tray is changed. However, since ICs of a high occurrence rate, that is, a large number of ICs are reloaded while changing the second tray to be reloaded ICs of the low occurrence category, the reloading operation of ICs can be continued during changing the second trays. Consequently, the number of ICs to be processed per time can be increased.

Also, when first trays are placed at least in two positions and are controlled so that when ICs to be reloaded to a corresponding second tray from one first tray run out, reloading is performed from other first tray to the second tray, it is no longer necessary to wait for a first tray and the number of ICs to be processed per time can be increased.

At this time, when it is controlled so that the ICs are reloaded from the other first tray while the other first tray is conveyed to a position of one tray, the waiting time becomes further less and the number of ICs to be processed per time can be further increased.

Also, when first trays are placed at least in two positions and are controlled so that reloading of ICs is performed from the other tray to the second tray at the same time of reloading ICs from one first tray to the second tray run out, it is no longer necessary to wait for a first tray and the number of ICs to be processed per time can be also increased.

Furthermore, by providing a buffer section between a first tray and a second tray, when a second tray for sorting ICs held on a first tray does not exist, and is controlled so as to temporality reloading in the buffer section, the reloading operation is not interrupted and ICs of a low occurrence category can be reloaded together in the second tray, so that the changing time of the second tray can be reduced.

### BRIEF DESCRIPTION OF THE DRAWINGS

These and other objects and features of the present invention will be explained in more detail with reference to the attached drawings, wherein:

FIG. 1 is a perspective view of an electric device testing apparatus wherein a sorting control method of tested ICs according to an embodiment of the present invention;

FIG. 2 is a schematic view of a handling method of ICs and trays in the electric device testing apparatus in FIG. 1;

FIG. 3 is an enlarged view of a loader section and an unloader section of an electric device testing apparatus to which a sorting control method of tested ICs according to the present invention;

FIG. 4 is a flow chart of a sorting control method of tested ICs according to an embodiment of the present invention; and

FIG. 5 is a flow chart of a subroutine of a step 5 in FIG. 4.

### DESCRIPTION OF THE PREFERRED EMBODIMENTS

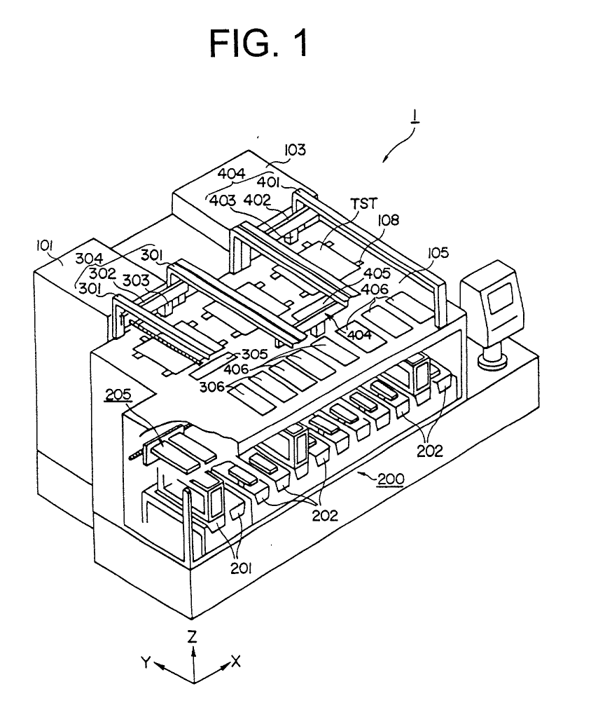

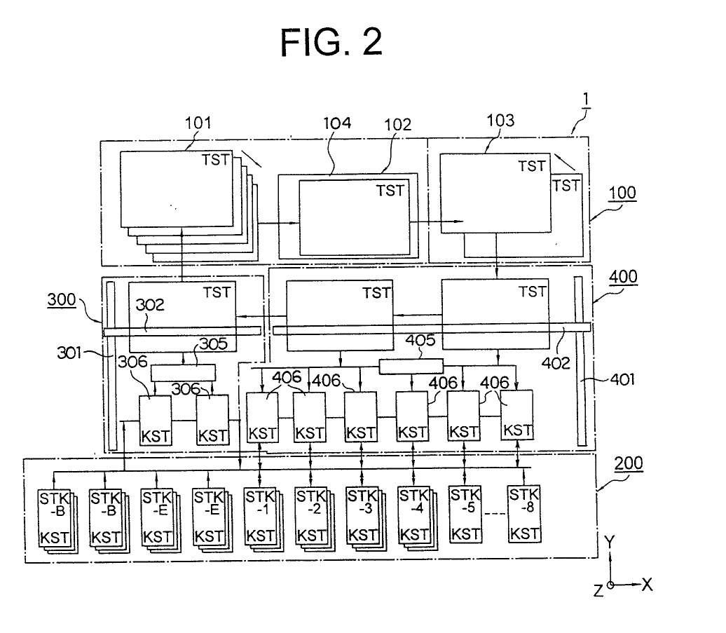

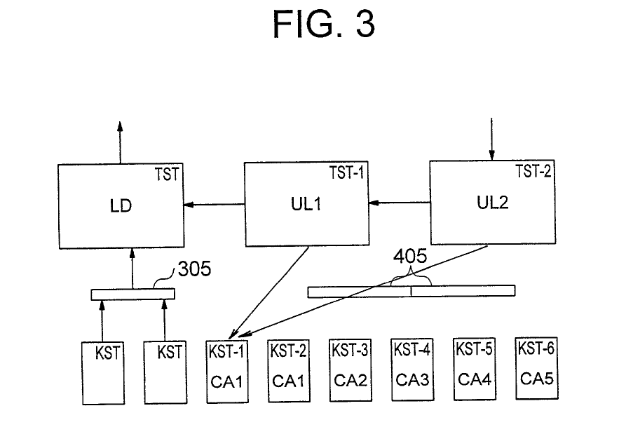

FIGS. 2 and 3 are views for understanding a method of handling trays in an electric device testing apparatus of an embodiment and partially shows by a plan view members actually arranged aligned in the vertical direction. Therefore, the mechanical (three-dimensional) structure will be explained with reference to FIG. 1.

As shown in FIG. 1 and FIG. 2, an electric device testing apparatus 1 comprises a chamber section 100 including a test head, a tray magazine 200 which holds the ICs to be tested or classifies and stores the tested ICs, a loader section 300 which sends the tested ICs into the chamber section 100, and an unloader section 400 for classifying and taking out tested ICs which had been tested in the chamber section 100.

Note that in the explanation below, a case where a sorting control method of tested ICs of the present invention is applied in a chamber type electric device testing apparatus 1 is described, but the sorting control method of tested ICs of the present invention can be applied to any handlers wherein trays for holding ICs to be tested (corresponding to a first tray in the present invention and will be also referred to as a test tray TST hereinafter) are used and is not limited to the chamber type electric device testing apparatus below.

Tray Magazine 200

The tray magazine 200 is provided with a pre-test IC stocker 201 for holding ICs to be tested and a post-test IC stocker 202 for holding ICs classified in accordance with the test results.

These pre-test IC stocker 201 and post-test IC stocker 202, a detailed illustration thereof is omitted, are each comprised of a frame-shaped tray support frame and an elevator able to enter from under the tray support frame and move toward the top. The tray support frame supports in it a plurality of stacked customer trays KST (corresponding to a second tray in the present invention). The stacked customer trays KST are moved up and down by the elevator.

The pre-test IC stocker 201 holds stacked customer trays KST on which the ICs to be tested are held, while the post-test IC stocker 202 holds stacked customer trays KST on which ICs finished being tested are suitably classified.

The upper portion of the pre-test IC stocker 201 and post-test IC stocker 202, there is provided a tray transfer arm 205 which moves all over the range of the pre-test stocker 201 and the post-test stocker 202 in the direction they are aligned between the board 105. In this example, since openings 306 and 406 of the loader section 300 and the unloader section 400 are formed immediately above the pre-test IC stocker 201 and post-test IC stocker 202 (without deviating in the Y-axis direction), the tray transfer arm 205 is also movable only in the directions of X-axis and Y-axis. Note that in accordance with the positional relationship of the tray magazine 200 and the loader section 300 or the unloader section 400, the tray transfer arm 205 may be made to be movable in all directions of X, Y and Z axises.

The tray transfer arm 205 is provided with a pair of tray magazines for holding the customer trays being in an alignment to the left and the right (in the X-axis direction) to each other, and transfers the customer trays between the loader section 300 and the unloader section 400 and between the pre-test IC stocker 201 and post-test IC stocker 202.

Note that since the pre-test IC stocker 201 and the post-test IC stocker 202 are structured the same, the numbers of the pre-test IC stocker 201 and the post-test IC stocker 202 may be suitably set in accordance with need. In the example shown in FIG. 1 and FIG. 2, the pre-test IC stocker 201 is provided with two stockers STK-B and provided next to that with two empty stockers STK-E to be sent to the unloader section 400, while the post-test IC stocker 202 is provided with eight stockers STK-1, STK-2, . . . , STK-8 and can hold ICs sorted into a maximum of eight classes according to the test results. For example, in addition to classifying ICs as good and defective, it is possible to divide the good ICs into ones with high operating speeds, ones with medium speeds, and ones with low speeds and the defective ICs into ones requiring retest etc.

Loader Section 300

The above-mentioned customer tray KST is conveyed to the loader section 300, where the ICs to be tested loaded on the customer tray KST are reloaded on the test tray TST stopped at the loader section 300.

The X-Y conveyor 304 is used as an IC conveying apparatus for reloading the ICs to be tested from the customer tray KST to the test tray TST, as shown in FIG. 1 and FIG. 2, which is provided with two rails 301 laid over the top of the board 105, a movable arm 302 able to move back and forth in the direction of Y-axis between the test tray TST and a customer tray KST by these two rails 301, and a movable head 303 supported by the movable arm 302 and able to move in the direction of X-axis along the movable arm 302.

The movable head 303 of the X-Y conveyor 304 has suction heads attached facing downward. The suction heads move while drawing out air to pick up the ICs to be tested from the customer tray KST and reload the ICs on the test tray TST. For example, about eight suction heads are provided for the movable head 303, so it is possible to reload eight ICs at one time on the test tray TST.

Note that in a general customer tray KST, indentation pockets for loading the ICs to be tested are formed relatively larger than the shapes of the ICs, so the positions of the ICs in a state held on the customer tray KST can vary largely. Therefore, if the ICs are picked up by the suction heads and conveyed directly to the test tray TST in this state, it becomes difficult for the ICs to be dropped accurately into the IC receiving indentations formed in the test tray TST.

Therefore, in the electronic devices testing apparatus 1 of the present embodiment, an IC position correcting means called a preciser 305 is provided between the set position of the customer tray KST and the test tray TST. This preciser 305 has relatively deep indentations surrounded with inclined surfaces at their circumferential edges, so when ICs picked up by the suction heads are dropped into these indentations, the drop positions of the ICs are corrected by the inclined surfaces. Due to this, the positions of the eight ICs with respect to each other are accurately set and it is possible to pick up the correctly positioned ICs by the suction heads once again and reload them on the test tray TST and thereby reload the ICs precisely in the IC receiving indentations formed in the test tray TST.

The board 105 of the loader section 300 is provided with a pair of openings 306, 306 arranged so that the customer trays KST carried to the loader section 300 can be brought close to the top surface of the board 105. Each of the openings 306 are provided with a holding hook (not illustrated) for holding the customer tray KST conveyed to the opening 306, and the customer tray KST is held in the position that the top surface thereof faces the surface of the board 105 via the opening 306.

Further, an elevator table (not illustrated) for elevating or lowering a customer tray KST is provided below the openings 306. A customer tray KST emptied after reloading of the ICs to be tested is placed on here and lowered and the empty tray is passed to the lower tray magazine of the tray transfer arm 205.

Chamber Section 100

The electronic device tasting apparatus 1 is an apparatus for testing (inspecting) whether an IC is operating suitably in a state being applied a high temperature or low temperature thermal stress or not applying any thermal stress to the IC, and classifies the ICs in accordance with the test results. The operating test in the state with thermal stress applied is performed by reloading the ICs from a customer tray KST carrying a large number of ICs to be tested to a test tray TST conveyed through the inside of the electronic devices testing apparatus 1.

The test tray TST is loaded with the ICs to be tested in the loader section 300 and then conveyed to the chamber section 100. The ICs are tested in the chamber section 100 in the state being carried on the test tray TST. Then, after the tested ICs are conveyed out to the unloader section 400, where the ICs are reloaded to the customer trays in accordance with the results of the tests. Note that the test tray TST emptied by reloading the tested ICs to the customer trays KST is sent back to a constant temperature chamber 101 via the loader section 300 by a test tray conveying apparatus.

The chamber section 100 comprises a constant temperature chamber 101 for giving a desired high temperature or low temperature thermal stress to the ICs to be tested carried on the test tray TST, a test chamber 102 for making the ICs contact the test head 104 in a state given the thermal stress by the constant temperature chamber 101, and an unsoak chamber 103 for removing the given thermal stress from the ICs tested in the test chamber 102.

In the unsoak chamber 103, when a high temperature was applied in the constant temperature chamber 101, the ICs to be tested are cooled by blowing in air to return them to room temperature. Alternatively, when a low temperature of, for example, about −30° C. has been applied in the constant temperature chamber 101, it heats the ICs by hot air or a heater etc. to return them to a temperature where no condensation occurs. Next, the thus treated ICs are conveyed out to the unloader section 400.

Unloader Section 400

The unloader section 400 is provided with X-Y conveyors 404, 404 of the same structure as the X-Y conveyor 304 provided at the loader section 300. The X-Y conveyors 404, 404 reload the post-test ICs from the test tray TST carried out to the unloader section 400 to the customer tray KST.

The board 105 of the unloader section 400 is provided with six openings 406 arranged so that the customer trays KST carried to the unloader section 400 can be brought close to the top surface of the board 105. Each of the openings 406 is provided with a holding hook (not illustrated) for holding the customer tray KST conveyed to the opening 406, and the customer tray KST is held in the position that the top surface thereof faces the surface of the board 105 via the opening 406. The specific configuration of the holding hook is not particularly limited, but for example it can mechanically grip the customer tray KST or hold the customer tray KST by a suction means.

An elevator table (not illustrated) for elevating or lowering a customer tray KST is provided below the openings 406. A customer tray KST becoming full after being reloaded with the tested ICs is placed on here and lowered and the full tray is passed to the lower tray magazine of the tray transfer arm 205. Note that instead of the elevator table, an elevator 204 of the stocker STK positioned right below the respective openings 406 may be used for elevating and lowering the customer tray KST.

Note that in the electronic devices testing apparatus 1 of the present embodiment, a buffer section 405 is provided between the test tray TST and the opening 406 of the unloader section 400, and ICs of a category rarely appearing are stored temporarily at this buffer section 405.

Sorting Control Method of Tested ICs

In an electric device testing apparatus 1, as shown in FIG. 3, a maximum of six customer trays KST can be arranged to the openings 406 of the unloader section 400. Accordingly, a maximum of six sortable categories is possible in real time, but two customer trays are assigned to ICs of a category having a high occurrence rate.

When the occurrence rate of a category CA1 is the highest in an example shown in FIG. 3, two customer trays are assigned for customer trays KST for holding ICs in this category CA1 and one customer tray KST is assigned to each one of other categories CA2 to CA5.

Specifications of sorting categories are not particularly limited, but for example it is possible to divide good ICs into ones with high operating speeds (category CA1), ones with medium speeds (category CA2), and ones with low speeds (category CA3), defective ICs (category CA4) and ones requiring retest (category CA5).

Also in the present example, two customer trays KST are assigned to the category having the highest occurrence rate, but when occurrence rates of the two highest categories are almost the same, the two categories are assigned to three customer trays and tested ICs are reloaded so that one of the three trays may be used for any of the two categories.

An operation will be explained next.

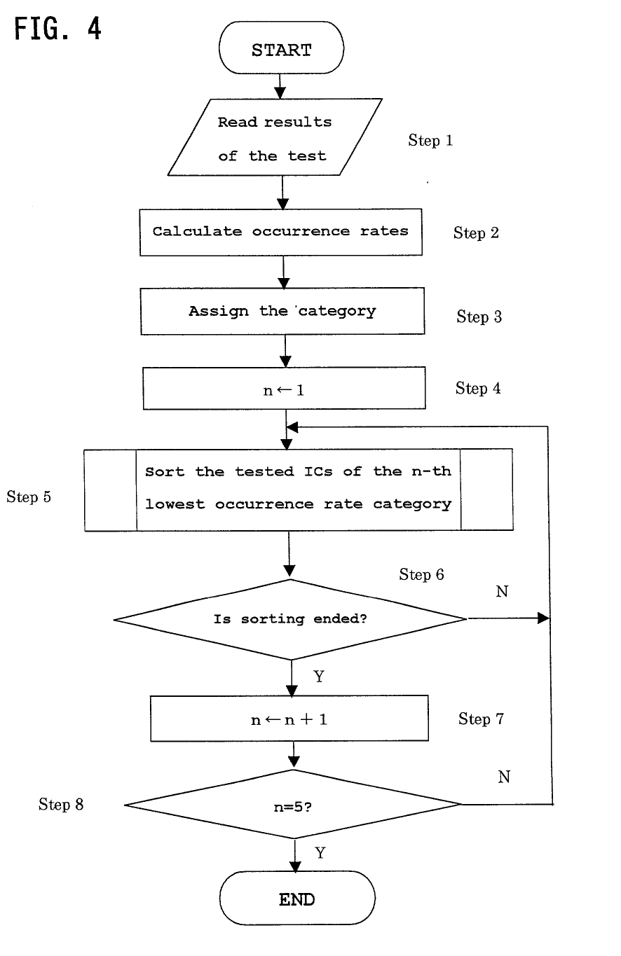

Here, an explanation will be made with reference to FIG. 3 to FIG. 5 on a series of operations of reloading tested ICs to the six customer trays KST arranged at the openings 406 from the test tray TST of the unloader section 400 while sorting the ICs. Note that two test trays TST-1 and TST-2 are placed at positions UL1 and UL2 of the unloader section 400, and the test trays TST-1 and TST-2 are filled with tested ICs, which are reloaded to six customer trays KST-1 to KST-6 set at the openings 406.

First, results of the test at the test head 104 are read and occurrence rates of respective categories are calculated for the tested ICs loaded on the test trays TST-1 and TST-2 placed respectively at the unloader section UL1 and UL2 at present (step 1 and 2). Assuming that ones with high operating speeds accounted for 89%, ones with medium speeds 5%, ones with low speeds 3%, defective ICs 2% and ones requiring retest 1%.

In step 3, the customer trays KST-1 to KST-6 are assigned based on the occurrence rates of categories analyzed in the step 2. At this time, the category of the ones with high operating speeds having the highest occurrence rate of 89% is made CA1 to which two customer trays KST-1 and KST-2 are assigned, while other categories CA2 to CA5 are made to be ones with medium speeds, ones with low speeds, defective ICs and ones requiring retest and successively assigned customer trays KST-3 to KST-6. Note that the assignment of categories to the customer trays is not limited to the present embodiment, and for example, when there are almost no changes in the occurrence rates of tested ICs, the assignment may be made in advance. Also, categories having almost no changes may be assigned in advance and only changing categories may be assigned each time.

Next, “1” is set to “n” in step 4 and moving on to step 5, where sorting of tested ICs of of the n-th lowest occurrence rate category starts. Here, since it is the first sorting, tested ICs of the lowest occurrence rate, that is ones requiring retest (1%), are sorted. The X-Y conveyor 404 is used for the reloading.

When sorting of the ones requiring retest having the lowest occurrence rate is ended in the step 5, the procedure moves on to step 7 where “1” is added to “n”, then goes back to the step 5. Namely, tested ICs of the second lowest occurrence rate, a category of defective (2%), are sorted. This operation is continued until sorting is ended on tested ICs of a category having the fifth lowest occurrence rate, that is, a category having the highest occurrence rate, which is a category of ones with high operating speeds (89%) here (step 8).

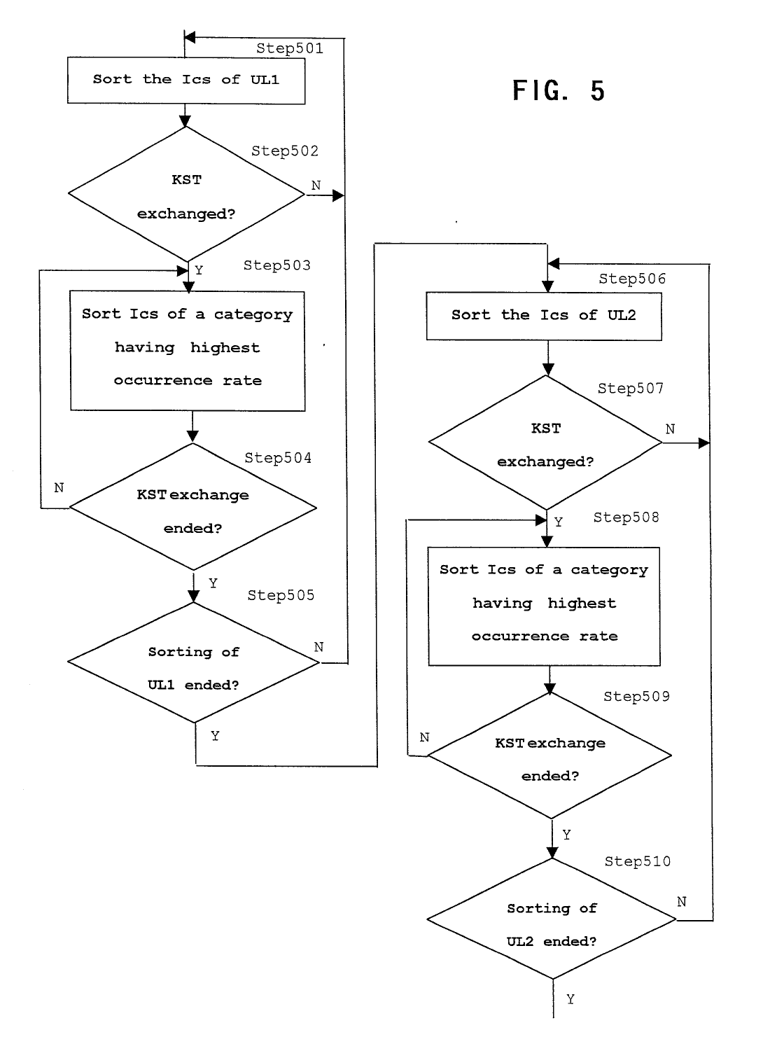

A subroutine of the step 5 will be explained with reference to FIG. 5.

In the step 5, when performing sorting of tested ICs of a category having the n-th lowest occurrence rate, sorting starts from the tested ICs on the test tray TST-1 of the unloader section UL1 first in step 501. Then, in step 505, when all of the tested ICs of a category under being sorted at present are sorted from the test tray TST-1 of the unloader section UL1, the procedure moves on to step 506, where the tested ICs to be sorted to the category is reloaded to the customer tray from the test tray TST-2 of the adjacent unloader section UL2. The above operation is performed until the tested ICs to be sorted to that category end up (step 510) or the customer tray for the tested ICs of the category is filled up and a new empty tray is set.

Namely, in step 502, for example, when the customer tray KST-6 for the tested ICs to be sorted to the category CA5 which is ones requiring retest is filled up and operation of exchanging with a new empty tray starts, the procedure goes on to step 503, where tested ICs to be sorted to a category having the highest occurrence rate, that is a category CA1 of the ones with high operating speeds here, among tested ICs held on the test tray TST-1 of the unloader section UL1 are reloaded to the corresponding customer trays KST-1 and KST-2. This operation is performed until the exchange of the customer tray KST-6 corresponding to the category CA5 of the above ones requiring retest is ended in the step 504. Furthermore, this operation is performed while sorting tested ICs held on the test tray TST-2 of the unloader section UL2 (step 507 to step 509).

Since the number of ICs of the category CA1 having the high occurrence rate, ones with high operating speeds, is large, reloading starts from the customer tray KST-1. In the present embodiment, two customer trays KST-1 and KST-2 are assigned for the ones with high operating speeds, so even when one customer tray KST-1 becomes full and is being exchanged, the remaining ICs of a category CA1 of the ones with high operating speeds on the other customer tray may be reloaded, thus the reloading operation is not interrupted. As a result, it is possible to continuously perform the reloading operation and the number of ICs to be processed per time can be increased.

Also, in the present embodiment, reloading starts from ICs of a category having a low occurrence rate, and when the customer tray for the category is being exchanged, sorting is performed on ICs of a high occurrence rate, that is a large number of ICs, so the reloading operation of ICs can be continued even during exchanging the customer tray, therefore, the number of ICs to be processed per time can be increased.

Furthermore, in the present embodiment, when ICs to be sorted end up in the unloader section UL1, sorting is performed also from not only an unloader section UL1 but the adjacent unloader section UL2, thus, it becomes unnecessary to wait for the test tray TST and thereby the number of ICs to be processed per time can be increased.

At this time, even when the test tray TST-2 at the unloader section UL2 is being conveyed to the unloader section UL1, if sorting is performed by synchronizing with the x-Y conveyor, the waiting time becomes further less and the number of ICs to be processed per time can be further increased.

Note that the embodiments explained above were described to facilitate the understanding of the present invention and not to limit the present invention. Accordingly, elements disclosed in the above embodiments include all design modifications and equivalents belonging to the technical field of the present invention.

For example, by using the buffer section 405 provided between the test trays TST-1 and TST-2 and the customer tray KST, when a customer tray KST of an objected category is not placed at an opening 406, it may controlled that the ICs may be temporally reloaded on the buffer section 405 and reloading of the ICs on the buffer section 405 is performed when a customer tray for that category is set at any one of the openings.

1. A sorting control method of tested ICs for sorting and reloading tested ICs held on a first tray to second trays in accordance with test results, including the steps of:
calculating from the test results an occurrence rate of each category of tested ICs held on said first tray; and
reloading ICs of a category having a high occurrence rate to two or more second trays.

2. A sorting control method of tested ICs for sorting and reloading tested ICs held on a first tray to second trays in accordance with test results, including the steps of:
calculating from the test results an occurrence rate of each category of tested ICs held on said first tray; and
starting reloading from ICs of a category having a low occurrence rate and when a second tray for holding ICs of the category is being changed, reloading of ICs of a category having a high occurrence rate is performed.

3. A sorting control method of tested ICs as set forth in claim 1, wherein when first trays are placed respectively in at least two positions and ICs to be reloaded from one first tray to a corresponding second tray end up, reloading is performed from the other first tray to said second tray.

4. A sorting control method of tested ICs as set forth in claim 2, wherein when first trays are placed respectively in at least two positions and ICs to be reloaded from one first tray to a corresponding second tray end up, reloading is performed from the other first tray to said second tray.

5. A sorting control method of tested ICs as set forth in claim 3, wherein even when said other first tray is being conveyed to a position of said one first tray, reloading of ICs from the other first tray is performed.

6. A sorting control method of tested ICs as set forth in claim 4, wherein even when said other first tray is being conveyed to a position of said one first tray, reloading of ICs from the other first tray is performed.

7. A sorting control method of tested ICs as set forth in claim 1, wherein when first trays are placed respectively in at least two positions and ICs are reloaded from one first tray to a second tray, while ICs are reloaded from the other first tray to said second tray.

8. A sorting control method of tested ICs as set forth in claim 2, wherein when first trays are placed respectively in at least two positions and ICs are reloaded from one first tray to a second tray, while ICs are reloaded from the other first tray to said second tray.

9. A sorting control method of tested ICs as set forth in claim 1, comprising a buffer section between said first tray and said second tray, and when a second tray to which ICs held on said first tray are sorted is not placed, the ICs are temporally reloaded on said buffer section.

10. A sorting control method of tested ICs as set forth in claim 2, comprising a buffer section between said first tray and said second tray, and when a second tray to which ICs held on said first tray are sorted is not placed, the ICs are temporally reloaded on said buffer section.
